(19) United States
(12) Patent Application Publication
(10) Pub. No.: US 2006/0113647 A1
(43) Pub. Date: Jun. 1, 2006

(54) Semiconductor device with improved heat dissipation

(75) Inventors: Ulrich Kasberger, Munchen (DE); Manfred Moser, Dachau (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/207,196

(22) Filed: Aug. 19, 2005

(30) Foreign Application Priority Data
Sep. 2, 2004 (DE) 10 2004 042 563.9

(51) Int. Cl. H01L 23/02

(52) U.S. Cl. 257/678

(57) ABSTRACT

The invention relates to a semiconductor module with at least one semiconductor modular printed circuit board, which offers an improvement of the heat dissipation or a more efficient heat transport from the semiconductor chip, e.g. a memory chip or a logic chip, to the modular printed circuit board. An intermediate layer of heat-conducting material is provided between the semiconductor chip and the modular printed circuit board, the intermediate layer dissipating the heat generated by the semiconductor chip to the modular printed circuit board. Thus, the heat generated during operation in the semiconductor chip is better dissipated to the modular printed circuit board, which improves the cooling of the semiconductor chips and thus reduces their operating temperature.

### CLAIM FOR PRIORITY

This application claims the benefit of priority to German Application No. 10 2004 042 563.9 which was filed in the German language on Sep. 2, 2004 the contents of which are hereby incorporated by reference.

### TECHNICAL FIELD OF THE INVENTION

The invention relates to a semiconductor device, in particular a semiconductor modular printed circuit board with one or a plurality of semiconductor chips, such as memory chips or logic chips, respectively, with improved heat dissipation.

### BACKGROUND OF THE INVENTION

In semiconductor logic chips, integrated circuits are arranged during the manufacturing process by numerous processing steps, which are capable of performing logic functions, i.e. of processing data in correspondence with predetermined operations, in particular in accordance with a particular program. A semiconductor memory chip such as a RAM (Random Access Memory) semiconductor memory chip, comprises a plurality of memory cells with one capacitor each that is connected with a so-called selection transistor. By the specific applying of a voltage at the appropriate selection transistor, it is possible to store electric charge as an information unit (bit) in the capacitor in a controlled manner during a write process. This information content may be recalled again during a read out process via the selection transistor.

A RAM memory device is a memory with optional access, i.e. data may be stored under a particular address and be read out again under this address later. Since it is intended to accommodate as many memory cells as possible in a RAM memory device, one has been trying to realize same as simple as possible and on the smallest possible space.

In the case of SRAM (Static Random Access Memory) memory devices, the individual memory cells consist of few, for instance 6, transistors. The memory cells of so-called DRAM (Dynamic Random Access Memory) memory devices, on the contrary, comprise in general only one single, correspondingly controlled capacitive element, e.g. a trench capacitor, with the capacitance of which one bit each can be stored as charge. This charge, however, remains for a short time only in a DRAM. Therefore, a so-called “refresh” must be performed regularly, e.g. approximately every 64 ms, where the information content has to be written in the memory cell again. In contrast to that, no “refresh” has to be performed in the case of SRAMs since the data stored in the memory cell remain stored as long as an appropriate supply voltage is fed to the SRAM. In the case of non-volatile memory devices (NVMs), e.g. EPROMs, EEPROMs, and flash memories, the stored data remain, however, stored even when the supply voltage is switched off.

In real systems of non-volatile memory devices, the stored charge, however, will not remain in the capacitor for any long time, which may result in a loss of information. Due to the scaling of modern memory devices, the reasons for the loss of information are, on the one hand, based on basic physical effects such as the scattering of charge carriers, the recombination at defective places, and interaction effects. On the other hand, the loss of information is also caused by so-called leaking paths that are generated during the manufacturing or processing of the memory devices, e.g. unsaturated bonds at interfaces between different materials as well as differing structure dimensions due to process fluctuations.

In both cases, these leaking paths result in that the information stored in the capacitor has to be renewed in time before it is lost. The time span during which sufficiently many charge carriers remain in the capacitor that they can be read out as the same information as they were written in, is referred to as “retention time”. According to experience, the retention time drops exponentially with the temperature of the chip within a particular range.

During the operation of the semiconductor device, temperatures of more than 100° C. are sometimes generated due to the electric currents flowing therein. Due to the increasing memory density and the ever higher clock frequencies, the operating temperatures of the semiconductor devices and of the semiconductor modules automatically increase, which makes efficient cooling ever more important. To ensure the longest possible retention even at elevated temperatures (up to approximately 120° C.), efficient cooling of the chips is required. The cooling of the semiconductor chips may be supported by an improved heat outflow.

There have already been known semiconductor modules, in particular from server applications, where the modular printed circuit board equipped with semiconductor chips is cooled by active cooling via a water circulation. The disadvantage of this method consists in that this kind of active cooling via a water circulation is related with large constructional effort, which is not economical for cost reasons in particular with applications for PCs (personal computers).

In other systems, e.g. personal computers and laptops, the heat produced in the semiconductor chips is additionally dissipated from the semiconductor chips by ventilators by means of convection. The disadvantage here is that, due to the position relative to the ventilator, not all the semiconductor modular printed circuit boards can be equally flown by air and thus are not cooled equally. The heat conduction is performed via the soldering contacts between the semiconductor chip and the printed circuit board on which the semiconductor chips are arranged.

### SUMMARY OF THE INVENTION

The present invention provides a semiconductor device, in particular a semiconductor modular printed circuit board that offers an improved heat dissipation or a more efficient heat transport from the semiconductor chip, such as a memory chip or a logic chip, to the modular printed circuit board.

The improved heat dissipation is solved in accordance with one embodiment of the present invention by a semiconductor device, in particular with a modular printed circuit board, on which there is provided at least one semiconductor chip, such as a memory chip and/or a logic chip, wherein an intermediate layer of heat conducting material is provided between the semiconductor chip and the modular printed circuit board, said intermediate layer dissipating the heat generated by the semiconductor chip to the modular printed circuit board.

This way, the heat generated in the semiconductor chip during operation is dissipated better to the modular printed circuit board, which improves the cooling of the semiconductor chips and thus reduces their operating temperature. Due to the so reduced operating temperature of the semiconductor chips during the operation, a more reliable retention of the information stored in the memory cells is ensured.

In another embodiment of the present invention, the space between the modular printed circuit board and the semiconductor chips arranged thereon is filled with the heat-conducting material between the chip and the modular printed circuit board. Usually, the chips are molded in packages, so that, according to the present invention, the space between the underside of the package of the semiconductor chip and the surface of the modular printed circuit board is filled as completely as possible with the heat-conducting material. In the case of the hitherto known semiconductor devices, this spacing has been filled with air which has only little heat conductivity. The filling of the spacing with heat-conducting material therefore results in higher heat conduction from the package of the semiconductor chip (memory chip or logic chip, respectively) to the surface of the modular printed circuit board that acts as a heat sink. The more efficient heat dissipation from the memory chip or logic chip, respectively, reduces the operating temperature of the chips and thus improves the retention time of the memory chips or the performance of the logic chips, respectively. By the lower operating temperature, the ohmic resistance is additionally reduced, which reduces the dissipation loss in the semiconductor chips.

In a preferred embodiment of the present invention, the heat-conducting material is electrically insulating and includes preferably of a silicate or silicone or Kapton, respectively. Silicates have the property of having an electrically insulating effect and have high thermal conductivity. The electrically insulating property of the heat-conducting material in the space between the modular printed circuit board and the semiconductor chips prevents an electrical short-circuit between the pins of the chips.

For connecting the chips to the modular printed circuit board, metallic soldering contacts are expediently provided, via which heat is also dissipated from the memory chip or logic chip, respectively, through the intermediate layer of heat-conducting material to the modular printed circuit board. Due to their metallic material, the soldering contacts indeed already have a good heat-conducting property, but this is decisively dependent on the cross-sectional area of the electrical pins to the chips and their soldering contacts.

In a further preferred embodiment of the present invention, the electrical pins of the chips to the modular printed circuit board including the soldering contacts thus have a cross-sectional area of the electrical pins of the chip to the modular printed circuit board that is as large as possible, which substantially improves the above-described heat transport. The cross-sections of the soldering contacts are chosen such that the safety distances between the electrical pins are kept so as to avoid electrical short-circuits or disturbing influences. By that, the heat is, additionally to the heat conduction through the intermediate layer of heat-conducting material, also dissipated as efficiently as possible through the soldering contacts to the modular printed circuit board.

Thus, an efficient dissipation of the heat is performed by heat conduction from the semiconductor chips to the modular printed circuit board that serves itself as a heat sink in that the modular printed circuit board dissipates the heat via its face to the ambient air by means of convection. Due to the thus reduced temperature of the semiconductor devices during operation, a more reliable retention of the information stored in the memory cells and a higher performance of the logic chips is enabled.

The electrical pins of the chips extend preferably through the intermediate layer and are thus surrounded by heat-conducting material. To optimize the dissipation of heat from the chips to the modular printed circuit board via the electrical pins of the chips, the metallic soldering contacts preferably have a contact face to the intermediate layer of heat-conducting material that is as large as possible. It is of particular advantage if the metallic soldering contacts of the chips are surrounded and contacted by the intermediate layer of heat-conducting material as completely as possible.

In yet another preferred embodiment of the present invention, the modular printed circuit board itself also substantially consists of a material of good thermal conductivity, so that the heat is dissipated from the semiconductor chips via the surface of the modular printed circuit board to the ambience at high heat flow. This heat flow may be further improved by increasing the surface of the modular printed circuit board, e.g. by cooling surfaces that are arranged at the modular printed circuit board and that are preferably metallic. Additionally or alternatively, preferably metallic cooling surfaces may be arranged at the chips themselves or at their packages in a known manner.

The present invention consequently includes improving the heat-conducting contact between the modular printed circuit board and the memory or logic chips arranged thereon so as to increase the dissipation of heat produced by the semiconductor chips during operation to the larger surface of the modular printed circuit board. In accordance with the invention, an efficient thermal contact between the chips (memory chips or logic chips, respectively) and the modular printed circuit board is effected by the (electrically insulating) filling material in the spacing between the packages of the semiconductor chips due to the very good heat conducting properties thereof.

The invention can, in particular, be applied for semiconductor modules that comprise memory chips or logic chips that generate heat to be dissipated. The present invention is particularly suited for semiconductor modular printed circuit boards where a number of memory chips and/or logic chips are arranged on the modular printed circuit board. Thus, the present invention is adapted to be also and precisely used with electronic data processing systems with one or a plurality of semiconductor devices of the above-described kind.

The invention is preferably applicable with SIMM modules (single in-line memory modules), and in particular with DIMM modules (dual in-line memory modules), which carry a number of memory chips each. In contrast to SIMM modules, DIMM modules are equipped with pins for the input and output of signals and for voltage supply not only on one side, but on both sides of the modular printed circuit board. The pins positioned on both sides of the modular printed circuit board for the input and output of signals and for voltage supply are connected with different memory chips. The invention is consequently especially applicable for electronic data processing systems in which semiconductor devices, in particular semiconductor modules with semiconductor modular printed circuit boards of the kind described here, are used.

### BRIEF DESCRIPTION OF THE DRAWINGS

In the following, the invention will be explained in more detail with reference to exemplary embodiments and the drawings. The drawings show:

FIG. 1 shows the underside of two semiconductor chips, e.g. a memory chip or a logic chip, according to prior art.

FIG. 2 shows the side view of two semiconductor chips, e.g. a memory chip or a logic chip, arranged on a printed circuit board in a known manner.

FIG. 3 shows the side view of two semiconductor chips, e.g. a memory chip or a logic chip, arranged on a printed circuit board according to a preferred embodiment of the present invention.

### DETAILED DESCRIPTION OF THE INVENTION

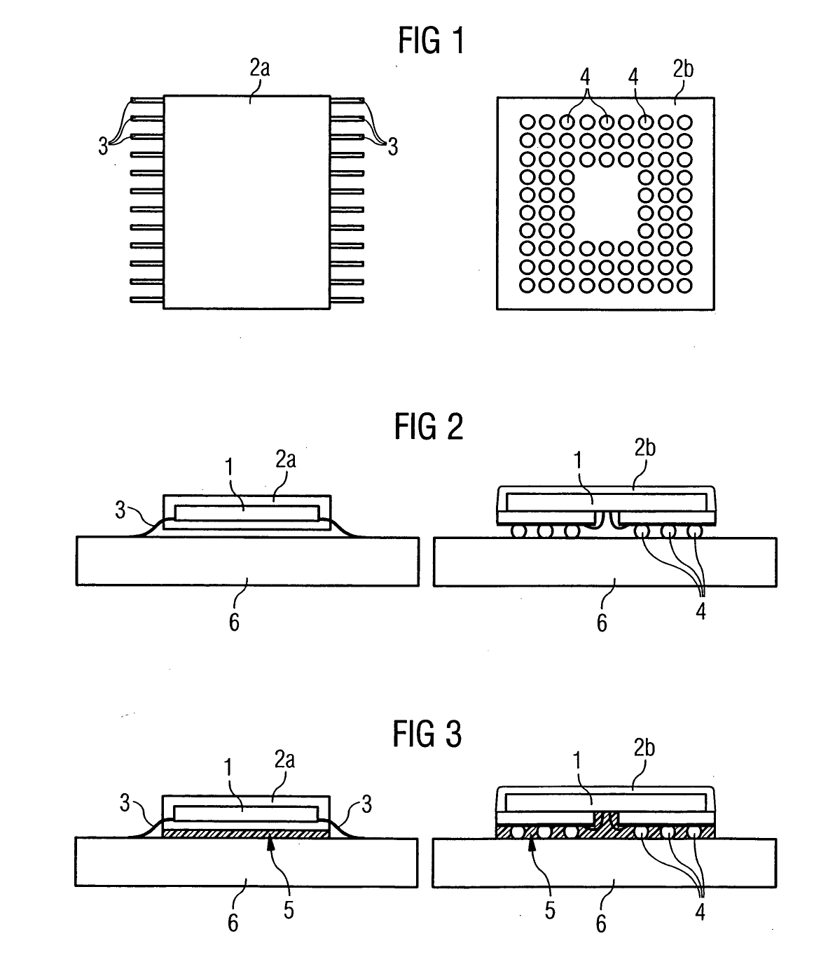

FIG. 1 shows schematic representations of the undersides of two semiconductor chips 1, e.g. a memory chip or a logic chip, according to prior art. On the chip 1, there are formed integrated circuits characterizing the chip 1 according to its function as a memory chip or a logic chip. The chip 1 is usually surrounded by a package 2a and 2b into which the chip 1 is molded during manufacturing during the so-called molding or packaging. At the left side of FIG. 1, the underside of a TSOP package 2a (Thin Small Outline Package) is illustrated schematically. In the case of TSOP packages 2a, the electrical contact between the chip 1 and the periphery, e.g. a modular printed circuit board, is established by means of soldering tags that project laterally from the package 2a and are, as a rule, bent downwards for inserting the semiconductor chip in an appropriate socket or directly in the modular printed circuit board.

At the right side of FIG. 1, the underside of a so-called FBGA package 2b (Fine Ball Grid Array or Fine-pitch Ball Grid Array, respectively) is illustrated schematically. In the case of FBGA packages 2b, the electrical pins of the chip 1 are connected with contact balls 4 via internal electrical lines within the package 2b, the contact balls 4 being arranged in a matrix at the underside of the FBGA package 2b. The electrical contact between the chip 1 and the periphery, e.g. a modular printed circuit board, is established in the case of FBGA packages 2b by the soldering of the contact balls 4 on a contact matrix (not shown) formed complementarily to the matrix of the contact balls 4.

FIG. 2 shows a schematic representation of the side view of two semiconductor chips 2a and 2b, e.g. a memory chip or a logic chip, which are arranged on a printed circuit board 6 in a known manner. The printed circuit board 6 may, for instance, be a modular printed circuit board 6 of a semiconductor module on which a number of semiconductor chips 2a and 2b, in particular memory chips and/or logic chips, are arranged. The semiconductor chips 2a and 2b are the semiconductor chips described above and illustrated in FIG. 1 with a TSOP package 2a and a FBGA package 2b. In all Figures, equal reference numbers have been used for identical parts, so that the following description of FIG. 2 concentrates on the kind of arrangement of the semiconductor chips 2a and 2b on the modular printed circuit board 6.

FIG. 2 illustrates the kind of arrangement of semiconductor chips 2a and 2b on a modular printed circuit board 6 according to prior art. Both semiconductor chips 2a and 2b each are placed onto the modular printed circuit board 6 with their undersides. In the case of the semiconductor chip with a TSOP package 2a, the electrical contact between the chip 1 and the modular printed circuit board 6 is established by means of the soldering tags 3 that project laterally out of the package 2a and are soldered with the modular printed circuit board 6. In the case of the semiconductor chip with a FBGA package 2b, the electrical contact between the chip 1 and the modular printed circuit board 6 is established by the soldering of the contact balls 4 on a contact matrix on the modular printed circuit board 6.

When the semiconductor chips are arranged on a printed circuit board there remains, as with the above-described package types, as a rule an air gap between the surface of the modular printed circuit board 6 and the package 2a and 2b. The heat produced during operation by the electric currents in the semiconductor chips 1 can therefore only be dissipated by heat radiation or via the soldering tags 3 or the contact balls 4, respectively, to the modular printed circuit board 6. Since air has just very little heat conductivity, the air gap between the packages of the semiconductor chips 2a, 2b and the surface of the modular printed circuit board 6 practically does not make any noteworthy contribution to the dissipation of the heat from the semiconductor chip 2a, 2b to the modular printed circuit board 6. Since the air gaps between the semiconductor chips 2a, 2b and the modular printed circuit board 6 are very small, an effective air circulation for cooling by means of convection is not given, either.

FIG. 3 shows a schematic representation of the side view of two semiconductor chips 2a and 2b, e.g. a memory chip or a logic chip, which are arranged on a printed circuit board 6 according to a preferred embodiment of the present invention. The arrangement in FIG. 3 corresponds largely to the arrangement illustrated in FIG. 2, so that the following description concentrates on the features deviating from the description of FIG. 2.

As has already been described above with respect to FIG. 2, in the case of semiconductor chips with TSOP packages 2a and with FBGA packages 2b there exists an air gap between the package underside and the printed circuit board surface, which obstructs the heat conduction from the semiconductor chips 2a and 2b to the modular printed circuit board 6. As may be seen from FIG. 3, the space between the package underside of the semiconductor chips 2a, 2b and the surface of the modular printed circuit board 6 is, according to the present invention, filled with a material 5 that has very good thermal conductivity. Furthermore, the heat-conducting material 5 between the modular printed circuit board 6 and the semiconductor chips 2a, 2b is electrically insulating so as to prevent an electrical short-circuit between the pins of the chips 1.

When filling the gap between the package underside of the semiconductor chips 2a, 2b and the surface of the modular printed circuit board 6 with the heat-conducting material 5, it has to be ensured that the material is in the best possible thermal contact with the package of the semiconductor chip 2a, 2b and with the modular printed circuit board 6. By the heat-conducting material establishing a large-area contact with the respective surfaces, a good heat flow can be generated between the semiconductor chips 2a, 2b and the modular printed circuit board 6, and thus a larger quantity of heat can be dissipated to the ambience than this is possible via the metallic soldering contacts 3, 4 of the semiconductor chips 2a, 2b alone.

According to the present invention, the heat produced by the chip is dissipated more efficiently via the package to the modular printed circuit board, and thus the operating temperature of the semiconductor chip is reduced, which enables a prolongation of the retention time or a more reliable retention, respectively, of the information stored in the memory cells, and a higher performance of the logic chips. Due to the lower operating temperature, the ohmic resistance in the integrated circuits of the chips is additionally reduced, which reduces the dissipation loss in the semiconductor chips.

The present invention is not restricted to an application for the two above-mentioned package types, which merely serve the exemplary explanation of the invention. The present invention is readily applicable also to other package types in which there remains a gap between the package underside and the surface of the printed circuit board.

1. A semiconductor device, comprising:
at least one modular printed circuit board on which at least one semiconductor chip is arranged; and
an intermediate layer of a heat-conducting material is provided between the semiconductor chip and the modular printed circuit board, the intermediate layer dissipating the heat generated by the memory chip or the logic chip, respectively, to the modular printed circuit board.

2. The semiconductor device according to claim 1, wherein the semiconductor chip comprises a package, and wherein a spacing between the package and the surface of the modular printed circuit board is filled substantially completely with said heat-conducting material.

3. The semiconductor device according to claim 1, wherein the heat-conducting material is electrically insulating and includes a silicate.

4. The semiconductor device according to claim 1, wherein metallic soldering contacts are provided between the semiconductor chip and the modular printed circuit board, via which heat is dissipated from the semiconductor device through the intermediate layer to the modular printed circuit board.

5. The semiconductor device according to claim 4, wherein the metallic soldering contacts comprise a contact face to the intermediate layer of heat-conducting material.

6. The semiconductor device according to claim 4, wherein the metallic soldering contacts are substantially completely surrounded and contacted by the intermediate layer of heat-conducting material.

7. The semiconductor device according to claim 1, wherein the metallic soldering contacts have a cross-sectional area that is as large as possible.

8. The semiconductor device according to claim 1, wherein the modular printed circuit board substantially consists of heat-conducting material and dissipates heat from the semiconductor chips via its face to the ambience.

9. The semiconductor device according to claim 1, wherein surface enlargements are provided at the modular printed circuit board by cooling surfaces arranged at the modular printed circuit board.

10. The semiconductor device according to claim 1, wherein a number of semiconductor chips are arranged on the modular printed circuit board.

11. An electronic data processing system comprising at least one semiconductor device, comprising:
at least one modular printed circuit board on which at least one semiconductor chip is arranged; and
an intermediate layer of a heat-conducting material is provided between the semiconductor chip and the modular printed circuit board, the intermediate layer dissipating the heat generated by the memory chip or the logic chip, respectively, to the modular printed circuit board.
